(19) United States
(12) Patent Application Publication
(10) Pub. No.: US 2025/0208211 A1
(43) Pub. Date: Jun. 26, 2025

(54) ABNORMALITY DETECTION DEVICE

(71) Applicant: TOYOTA JIDOSHA KABUSHIKI KAISHA, Toyota-shi (JP)

(72) Inventor: Eiji TAKAGI, Toyota-shi (JP)

(73) Assignee: TOYOTA JIDOSHA KABUSHIKI KAISHA, Toyota-shi (JP)

(21) Appl. No.: 18/963,942

(22) Filed: Nov. 29, 2024

(30) Foreign Application Priority Data
Dec. 20, 2023 (JP) 2023-214945

(51) Int. Cl. G01R 31/327; G01R 31/396

(52) U.S. Cl. CPC G01R 31/327; G01R 31/396

(57) ABSTRACT

An abnormality detection device for detecting an abnormality of a signal line connecting an output of an ignition switch of a vehicle and a battery pack, the abnormality detection device comprising: a monitoring unit that monitors a first signal indicating a voltage of a signal line, a second signal indicating an ON/OFF state of an ignition switch communicated in a network of the vehicle, and a third signal indicating an ON/OFF state of an ignition switch output from a shift-by-wire system of the vehicle; and a determination unit that determines whether an abnormality is present in the signal line based on the first signal, the second signal, and the third signal monitored by the monitoring unit.

### CROSS-REFERENCE TO RELATED APPLICATION

This application claims priority to Japanese Patent Application No. 2023-214945 filed on Dec. 20, 2023, incorporated herein by reference in its entirety.

### BACKGROUND

### 1. Technical Field

The present disclosure relates to an abnormality detection device that detects an abnormality related to an ignition switch of a vehicle.

### 2. Description of Related Art

Japanese Unexamined Patent Application Publication No. 2021-136740 (JP 2021-136740 A) discloses an abnormality detection device that can detect an abnormality in a signal line of an ignition switch connected to a battery pack. In the abnormality detection device, an abnormality in the signal line of the ignition switch is detected based on three signals, which are a Controller Area Network (CAN) signal indicating an ON/OFF state of the ignition switch, a voltage signal indicating a voltage corresponding to the ON/OFF state of the ignition switch, and a port input signal generated from a signal branched from the voltage signal.

### SUMMARY

In the abnormality detection device described in JP 2021-136740 A, it is necessary to receive the port input signal in order to detect an abnormality in the signal line of the ignition switch. Since the necessity arises to design a new circuit or to change an existing circuit in order to receive and control the port input signal, there is a risk of leading to an increase in a system cost, such as a complication of control or an expansion of a circuit scale. Accordingly, there is room for further examination of technology that detects an abnormality in a signal line of an ignition switch.

The present disclosure has been made in view of the problem, and an objective of the present disclosure is to provide an abnormality detection device that can detect an abnormality in a signal line of an ignition switch, while suppressing an increase in a system cost such as a complication of control or an expansion of a circuit scale.

In order to solve the problem, one aspect of the present disclosure technology is an abnormality detection device that detects an abnormality in a signal line connecting an output of an ignition switch of a vehicle and a battery pack, the abnormality detection device including a monitoring unit that monitors a first signal indicating a voltage of the signal line, a second signal indicating an ON/OFF state of the ignition switch communicated by a network of the vehicle, and a third signal indicating the ON/OFF state of the ignition switch output by a shift-by-wire system of the vehicle, and a determination unit that determines a presence or absence of an abnormality in the signal line based on the first signal, the second signal, and the third signal monitored by the monitoring unit.

According to the abnormality detection device of the present disclosure, since an existing third signal (SBW signal) is used in addition to a first signal (voltage signal) and a second signal (CAN signal), an abnormality in a signal line of an ignition switch can be appropriately detected, while suppressing a cost increase such as a complication of control or an expansion of a circuit scale.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a functional block diagram of an abnormality detection device and a peripheral portion thereof according to an embodiment of the present disclosure;

FIG. 2 is an exemplary process flow chart of the abnormality detection control executed by the abnormality detection device; and

FIG. 3 is an example of a processing flowchart of treatment control provided to a user when an abnormality is detected.

### DETAILED DESCRIPTION OF EMBODIMENTS

The abnormality detection device according to the present disclosure detects a sky fault which is one of abnormalities appearing on a signal line of an ignition switch by using an existing signal instead of using a new signal. As a result, it is possible to suppress complication of control, increase in circuit scale, and the like, and to prevent an increase in cost.

Hereinafter, an embodiment of the present disclosure will be described in detail with reference to the drawings.

### EMBODIMENT

### Configuration

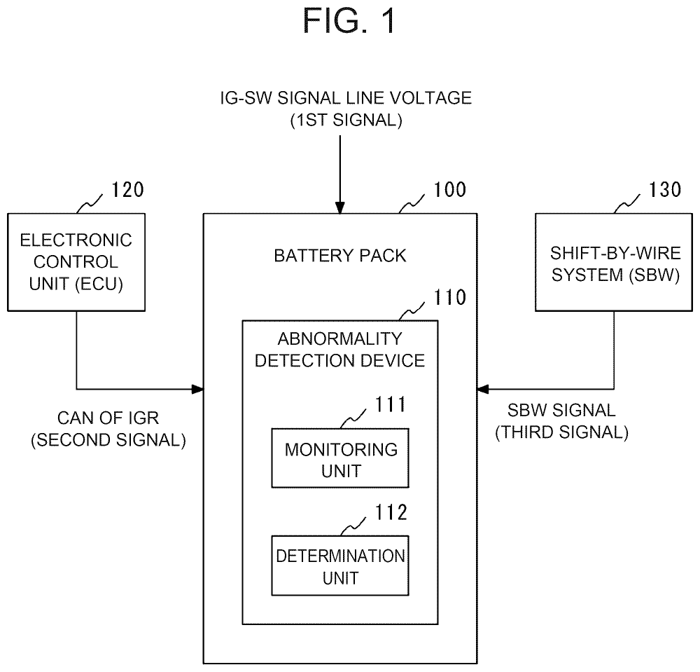

FIG. 1 is a schematic functional block diagram of an abnormality detection device 110 and a peripheral portion thereof according to an embodiment of the present disclosure. The functional blocks illustrated in FIG. 1 include a battery pack 100 incorporating an abnormality detection device 110, an electronic control unit 120, and a shift-by-wire system 130.

The battery pack 100, the electronic control unit 120, and the shift-by-wire system 130 are mounted on vehicles such as hybrid electric vehicle (HEV), plug-in hybrid electric vehicle (PHEV), and battery electric vehicle (BEV).

The battery pack 100 is a power source capable of supplying power to a device, a system, or the like (not shown) mounted on the vehicle. As the battery pack 100, a sub-battery (for example, a second battery module (SBM)) provided redundantly for backing up a main battery (for example, an auxiliary battery) that supplies electric power to an auxiliary system of a vehicle can be exemplified.

The battery pack 100 includes an abnormality detection device 110 including a monitoring unit 111 and a determination unit 112. Note that the battery pack 100 includes, in addition to the abnormality detection device 110, a battery that is a secondary battery configured to be chargeable and dischargeable, a DCDC converter that charges and discharges the electric power of the battery, and a control unit that controls the managing and DCDC converter of the battery, and the like.

The monitoring unit 111 is configured to monitor the first signal, the second signal, and the third signal described below. Then, the monitoring unit 111 notifies the determination unit 112 of the monitoring results of these three signals.

The first signal is a signal indicating a voltage of a signal line (hereinafter, referred to as a “IG-SW signal line”) connecting the output of the ignition switch (IG-SW) of the vehicle and the battery pack 100. The first signal is inputted to the battery pack 100, for example, by being connected from an IG-SW signal line by a zika line. Therefore, in the normal state, the first signal becomes a voltage value applied through the ignition switch when the ignition switch is in the ON state (IGR-ON), and becomes a voltage value near zero when the ignition switch is in the OFF state (IGR-OFF).

The second signal is a signal indicating the ON/OFF state of the ignition switch communicated from the electronic control unit 120 over CAN network. The second signal is inputted to the battery pack 100 by acquiring a desired CAN signal from CAN signal flowing through CAN network.

The third signal is a signal indicating the ON/OFF state of the ignition switch output from the shift-by-wire system 130. This third signal is input to the battery pack 100 by being directly output from the shift-by-wire system 130.

The determination unit 112 determines the presence or absence of an anomaly in IG-SW signal line based on the first signal, the second signal, and the third signal monitored by the monitoring unit 111. Determination of the presence or absence of this abnormality will be described later.

The electronic control unit 120 is an ECU mounted on a vehicle, and can be an ECU (for example, an extended body ECU) that controls the body system of the vehicle. The electronic control unit 120 is capable of outputting a CAN signal corresponding to the control state (conduction/disconnection) of the ignition relation (IGR) to CAN network in the vehicle as a second signal indicating the ON/OFF state of the ignition switch. CAN signal (second signal) in this IGR may be, for example, a signal indicating a logical value “1” when the ignition switch is in an ON state (IGR-ON) and a signal indicating a logical value “0” when the ignition switch is in an OFF state (IGR-OFF).

The shift-by-wire system (SBW) 130 is a control device that can change the gear stage of a transmission (not shown) by an electric signal. The shift-by-wire system 130 includes an electronic control unit (SBW_ECU) that converts a shift operation of a driver into an electric signal, an actuator (SBW_ACT) that changes a gear stage based on an electric signal instructed from the electronic control unit, and the like. The shift-by-wire system 130 of the present embodiment is capable of outputting a predetermined SBW signal to the battery pack 100 as a third signal when the ignition switch is in the OFF state (IGR-OFF). Examples of SBW signal (third signal) include a PWM signal (pulsed signal) having a predetermined duty cycle, which is outputted by the shift-by-wire system 130 as a pre-existing signal for permitting a transition to the sleep state.

### Basic Control

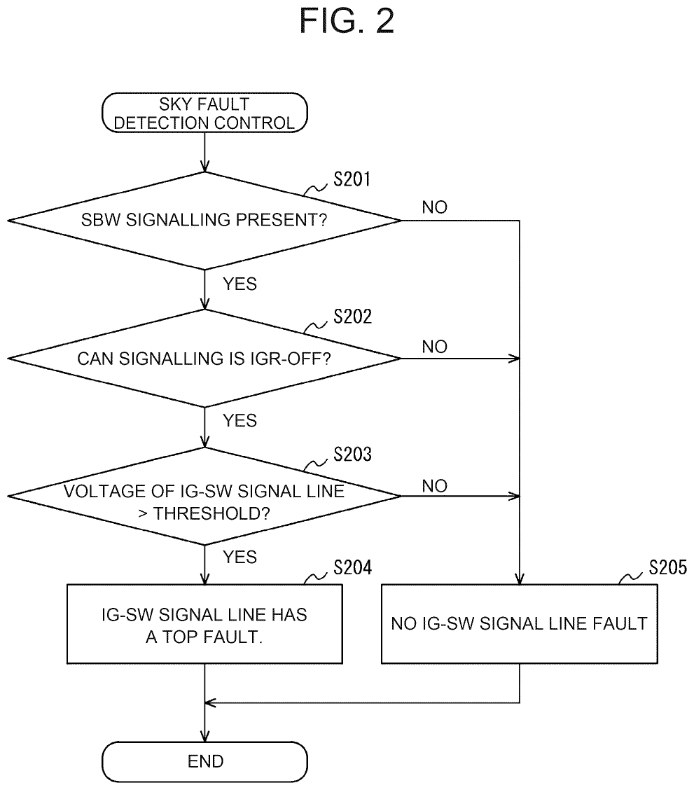

Next, with further reference to FIG. 2, control performed by the battery pack 100 according to an embodiment of the present disclosure will be described. FIG. 2 is a flow chart for explaining an exemplary process of the sky fault detection control of IG-SW signal line executed by the abnormality detection device 110 of the battery pack 100.

The sky fault detection control illustrated in FIG. 2 is started when a driver or the like presses a start/stop button to request the system to be stopped in a vehicle that is in a state of system activation capable of traveling. In accordance with this button operation, a process for switching the ignition switch from the ON state (IGR-ON) to the OFF state (IGR-OFF) is performed inside the vehicle.

### S201

The abnormality detection device 110 determines whether or not a SBW signal (third signal) outputted when the ignition switch is in the OFF state (IGR-OFF) is inputted from the shift-by-wire system 130. Since the shift-by-wire system 130 detects not only IGR-OFF but also all READY-OFF and IGP-OFF indicating the stoppage of the system and then outputs an SBW signal, the ignition switch is highly reliable. If an SBW signal is received from the shift-by-wire system 130 (S201, Yes), the process proceeds to S202. On the other hand, when an SBW signal is not inputted from the shift-by-wire system 130 (S201, No), the process proceeds to S205.

### S202

The abnormality detection device 110 determines whether or not the ignition switch of the vehicle is in the OFF state (IGR-OFF). This determination can be made based on whether or not CAN signal (second signal) of IGR related to the ignition switch sent by the electronic control unit 120 to CAN network is “information indicating IGR-OFF”. When CAN signal of IGR is “information indicating an IGR-OFF” (S202, Yes), the process proceeds to S203. On the other hand, when CAN signal of IGR is “information indicating IGR-ON” (S202, No), the process proceeds to S205.

### S203

The abnormality detection device 110 determines whether the voltage (first signal) of IG-SW signal line is larger than a predetermined threshold. This determination is made to determine whether the voltage of IG-SW signal line is indicative of an anomaly contrary to the condition of the ignition switch. In the present embodiment, the threshold value is set to a predetermined voltage capable of sufficiently determining a sky fault. If the voltage of IG-SW signal line is greater than the threshold (S203, Yes), the process proceeds to S204. On the other hand, when the voltage of IG-SW signal line is equal to or lower than the threshold (S203, No), the process proceeds to S205.

### S204

Although CAN signal (second signal) and SBW signal (third signal) of IGR both indicate that the ignition switch is in the OFF state (IGR-OFF), the abnormality detection device 110 determines that an abnormality occurs in which IG-SW signal line is in the sky because the voltage (first signal) of IG-SW signal line indicates that the ignition switch is in the ON state (IGR-ON). When it is determined that there is an anomaly, the sky fault detecting control of IG-SW signal line ends.

### S205

The abnormality detection device 110 determines that IG-SW signal line is normal because the voltage of IG-SW signal line (the first signal), CAN signal of IGR (the second signal), and SBW signal (the third signal) all indicate that the ignition switch is in the OFF state (IGR-OFF). If it is determined to be normal, the sky fault detecting control of IG-SW signal line ends.

In the sky fault detecting control of IG-SW signal line, when the voltage of IG-SW signal line (the first signal) and CAN signal of IGR (the second signal) are in conflict with each other, it is determined whether or not there is an anomaly in the sky fault in IG-SW signal line, considering the condition of the more reliable SBW signal (the third signal). By comprehensively determining the three signals, an anomaly in IG-SW signal line can be accurately detected.

### Applied Control

When it is determined that there is an abnormality in the occurrence of a sky fault in IG-SW signal line by the above-described sky fault detecting control of IG-SW signal line, it is possible to propose a treatment for the abnormality to a user of the vehicle such as a driver.

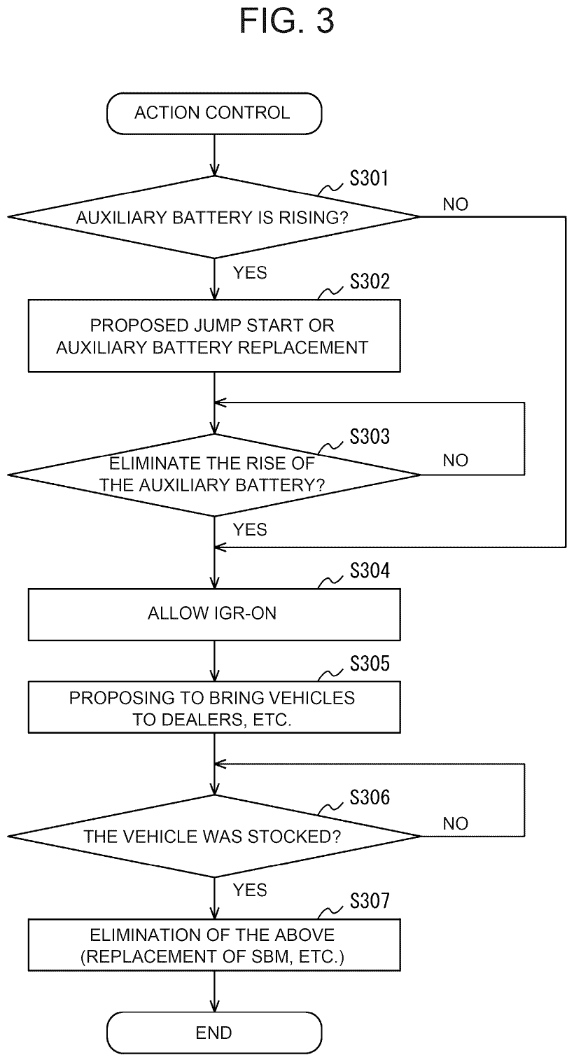

FIG. 3 is a flowchart illustrating an example of a procedure of the treatment control provided to the user when an abnormality is detected in IG-SW signal line. The treatment control illustrated in FIG. 3 may be performed by the abnormality detection device 110 of the battery pack 100, by another device mounted on the vehicle (for example, an ECU that manages an auxiliary battery, or the like), or by a plurality of in-vehicle devices cooperating with each other.

### S301

First, it is determined whether an increase in the auxiliary battery has occurred. The reason for determine the rise of the auxiliary battery is that, when IG-SW signal line is caught in the sky, the battery pack 100 cannot go to the sleep state while the system of the vehicle is stopped, and there is a possibility that a current continues to be supplied from the auxiliary battery to the battery pack 100. If the auxiliary battery is raised (S301, Yes), the process proceeds to S302. On the other hand, if the auxiliary battery has not been raised (S301, No), the process proceeds to S304.

### S302

To the user of the vehicle, it is proposed that a jump start is performed by connecting an external charger or the like to the auxiliary battery, and that the auxiliary battery is replaced with a new one. When a jump start or replacement of the auxiliary battery is proposed, the process proceeds to S303.

### S303

It is determined whether or not the rise of the auxiliary battery has been eliminated. When the rise of the auxiliary battery is eliminated (S303, Yes), the process proceeds to S304. If the increase of the auxiliary battery is not eliminated even after a predetermined period of time, it is highly likely that the user of the vehicle does not recognize the suggestion of S302, and thus the treatment control may be terminated.

### S304

Since the accessory battery has not risen or has been cleared, switching of the ignition switch from the OFF state (IGR-OFF) to the ON state (IGR-ON) by depressing the start/stop button is permitted.

### S305

It is suggested that vehicle users take the vehicle to a dealer, maintenance facility, etc. and perform the required repairs in relation to IG-SW signal line. When a vehicle is proposed to be brought to a dealer or the like, the process proceeds to S306.

### S306

It is determined whether or not the vehicle has been stored in a dealer, a maintenance factory, or the like. Whether or not the vehicle has been stored may be automatically determined based on, for example, position information of the vehicle, or may be manually determined by an operator of the dealer or the like. When vehicles are stored in a dealer or the like (S306, Yes), the process proceeds to S307. Note that, when the vehicles are not stored in the dealer or the like even after a predetermined period of time, there is a high possibility that an urgent response to the above-described S305 suggestion is not desired, and thus the treatment control may be terminated.

### S307

In dealers, maintenance plants, and other facilities, repairs are required to eliminate the occurrence of a sky fault in IG-SW signal line. Examples of the repair include replacement of the battery pack 100, replacement of IG-SW signal line, and an insulating process of the sky fault point. Upon completion of the repair, the treatment control ends.

### Operations and Effects

As described above, the abnormality detection device 110 according to the embodiment of the present disclosure monitors the first signal indicating the voltage of IG-SW signal line connecting the output of the ignition switch of the vehicle and the battery pack 100, the CAN signal (the second signal) indicating the ON/OFF state of the ignition switch communicated from the electronic control unit 120 in CAN network, and the SBW signal (the third signal) indicating the ON/OFF state of the ignition switch output from the shift-by-wire system 130 of the vehicle, and detects the abnormality of IG-SW signal line based on these three signals (the first signal, the second signal, and the third signal).

As described above, since the abnormality of IG-SW signal line is detected based on the conventional SBW signal (third signal) which is highly reliable with respect to the ON/OFF state of the ignition switch in addition to the voltage (first signal) and CAN signal (second signal) of IG-SW signal line conventionally used, it is possible to appropriately detect the abnormality of the signal line of the ignition switch while suppressing an increase in the control complexity and an increase in the circuit size.

Although an embodiment of the present disclosure has been described above, the present disclosure can be regarded as not only an abnormality detection device but also a method executed by the abnormality detection device, a program of the method, a computer-readable non-transitory storage medium storing the program, a vehicle including a battery pack including the abnormality detection device, and the like.

The abnormality detection device of the present disclosure can be used in a case where an abnormality related to an ignition switch of a vehicle is detected.

What is claimed is:

1. An abnormality detection device that detects an abnormality in a signal line connecting an output of an ignition switch of a vehicle and a battery pack, the abnormality detection device comprising:
a monitoring unit that monitors a first signal indicating a voltage of the signal line, a second signal indicating an ON/OFF state of the ignition switch communicated by a network of the vehicle, and a third signal indicating the ON/OFF state of the ignition switch output by a shift-by-wire system of the vehicle; and
a determination unit that determines a presence or absence of an abnormality in the signal line based on the first signal, the second signal, and the third signal monitored by the monitoring unit.

2. The abnormality detection device according to claim 1, wherein when the second signal and the third signal both indicate an OFF state of the ignition switch, the determination unit determines that an abnormality of the signal line being a sky fault occurs if the first signal indicates a voltage larger than a predetermined threshold.

3. The abnormality detection device according to claim 1, wherein the battery pack includes a sub-battery redundantly provided to back up a predetermined main battery mounted in the vehicle.
